(19) United States
(12) Patent Application Publication
(10) Pub. No.: US 2025/0081701 A1
(43) Pub. Date: Mar. 6, 2025

(54) BONDED SUBSTRATE, LIGHT-EMITTING DEVICE, METHOD OF MANUFACTURING BONDED SUBSTRATE, AND METHOD OF MANUFACTURING LIGHT-EMITTING DEVICE

(71) Applicant: NICHIA CORPORATION, Anan-shi (JP)

(72) Inventors: Hiroto KUME, Anan-shi (JP); Atsushi HOSOKAWA, Tokushima-shi (JP)

(73) Assignee: NICHIA CORPORATION, Anan-shi (JP)

(21) Appl. No.: 18/813,021

(22) Filed: Aug. 23, 2024

(30) Foreign Application Priority Data
Aug. 28, 2023 (JP) 2023-138416

(51) Int. Cl. H01L 33/64

(52) U.S. Cl. CPC H10H 20/8581; H10H 20/0365

(57) ABSTRACT

A bonded substrate includes a metal plate; a first ceramic; and a first metal body disposed between a first surface of the metal plate and a first surface of the first ceramic and disposed on 80% or more of a lateral surface continuous with the first surface of the first ceramic.

### CROSS-REFERENCE TO RELATED APPLICATIONS

The present application claims priority under 35 U.S.C. § 119 to Japanese Patent Application No. 2023-138416, filed Aug. 28, 2023, the contents of which is hereby incorporated by reference in its entirety.

### BACKGROUND

### 1. Technical Field

The present disclosure relates to a bonded substrate, a light-emitting device, a method of manufacturing a bonded substrate, and a method of manufacturing a light-emitting device.

### 2. Description of Related Art

In light-emitting devices including light-emitting elements such as light-emitting diodes, the mounted light-emitting elements are highly integrated and the amount of light emitted from the light-emitting elements is increased year by year. As a result, the amount of heat generated is increased and countermeasures against the heat are required.

As a substrate of a light-emitting device, a bonded substrate in which a copper-circuit plate is bonded to a ceramic plate by an active-metal brazing method is known, and a technique by which a large-sized bonded substrate is singulated into a plurality of bonded substrates is also known.

For example, a method has been reported in which, in order to prevent positioning deviation between a bonding material and a copper circuit plate during bonding, by using a positioning tool and a temporal-stick material, a plurality of copper-circuit plates are positioned and bonded onto a ceramic substrate having an area where a plurality of ceramic substrates are to be formed abreast, and then the ceramic substrate is divided between adjacent ones of the copper-circuit plates so as to manufacture a plurality of substrates (see Japanese Patent Publication No. 2014-175425, for example).

Further, in order to suppress warpage or deformation when manufacturing a large-sized substrate, a circuit substrate with a slit has been reported in which a dividing groove is formed in a surface on the circuit side of a ceramic circuit substrate or in both main surfaces of the ceramic circuit substrate, the dividing groove is 1.0 mm or more away from an end portion of a circuit pattern, and the thickness of a bottom portion of the dividing groove is in the range of 0.2 mm to 0.5 mm (see Japanese Patent Publication No. 2005-129625, for example).

### SUMMARY

Embodiments of the present disclosure can provide a bonded substrate that reduces the occurrence of internal delamination and chipping and has good thermal conductivity, and a method of manufacturing the bonded substrate.

A bonded substrate according to one embodiment of the present disclosure includes a metal plate; a first ceramic; and a first metal body disposed between a first surface of the metal plate and a first surface of the first ceramic and disposed on 80% or more of a lateral surface continuous with the first surface of the first ceramic.

Further, a light-emitting device according to one embodiment of the present disclosure includes the bonded substrate; and a light-emitting element disposed on the bonded substrate.

A method of manufacturing a bonded substrate according to one embodiment of the present disclosure includes disposing a first bonding member in a recess and on a first surface of a first ceramic plate, the first ceramic plate having the first surface, the recess recessed from the first surface, and a second surface opposite to the first surface; disposing a metal plate such that the first surface of the first ceramic plate and a first surface of the metal plate face each other with the first bonding member interposed therebetween; firing the first ceramic plate, the first bonding member, and the metal plate; polishing or grinding the second surface of the first ceramic plate in a stack in which a first metal body is obtained by the firing of the first bonding member, and the metal plate and the first ceramic plate are bonded together by the first metal body; and in the stack in which a portion of the first metal body is exposed through the first ceramic plate by the polishing or the grinding of the second surface of the first ceramic plate, cutting the stack from the metal plate to the first ceramic plate through the first metal body disposed in the recess.

Further, a method of manufacturing a light-emitting device according to one embodiment of the present disclosure includes manufacturing the bonded substrate by the method of manufacturing the bonded substrate; and disposing a light-emitting element on the bonded substrate.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1 is a side view schematically illustrating an example of a bonded substrate according to an embodiment.

FIG. 2 is a bottom view schematically illustrating the example of the bonded substrate according to the embodiment.

FIG. 3 is a cross-sectional view of the bonded substrate taken through the line III-III of FIG. 2.

FIG. 4 is a side view schematically illustrating another example of a bonded substrate according to an embodiment.

FIG. 5 is a bottom view schematically illustrating the other example of the bonded substrate according to the embodiment.

FIG. 6 is a cross-sectional view of the bonded substrate taken through the line VI-VI of FIG. 5.

FIG. 7 is a perspective view schematically illustrating a light-emitting device according to an embodiment.

FIG. 8 is a perspective view schematically illustrating the light-emitting device according to the embodiment, in which some components are not depicted.

FIG. 9 is a plan view schematically illustrating the light-emitting device according to the embodiment.

FIG. 10 is a cross-sectional view of the light-emitting device taken through the line X-X of FIG. 7.

FIG. 11 is a cross-sectional view of the light-emitting device taken through the line XI-XI of FIG. 7.

FIG. 12 is a flowchart illustrating an example of a method of manufacturing a bonded substrate according to an embodiment.

FIG. 13 is a flowchart illustrating an another example of a method of manufacturing a bonded substrate according to an embodiment.

FIG. 14 is a cross-sectional view schematically illustrating a manufacturing process in a method of manufacturing a bonded substrate according to an embodiment.

FIG. 15 is a cross-sectional view schematically illustrating the manufacturing process in the method of manufacturing the bonded substrate according to the embodiment.

FIG. 16 is a cross-sectional view schematically illustrating the manufacturing process in the method of manufacturing the bonded substrate according to the embodiment.

FIG. 17 is a cross-sectional view schematically illustrating the manufacturing process in the method of manufacturing the bonded substrate according to the embodiment.

FIG. 18 is a cross-sectional view schematically illustrating the manufacturing process in the method of manufacturing the bonded substrate according to the embodiment.

FIG. 19 is a cross-sectional view schematically illustrating the manufacturing process in the method of manufacturing the bonded substrate according to the embodiment.

FIG. 20 is a cross-sectional view schematically illustrating the manufacturing process in the method of manufacturing the bonded substrate according to the embodiment.

FIG. 21 is a cross-sectional view schematically illustrating the manufacturing process in the method of manufacturing the bonded substrate according to the embodiment.

FIG. 22 is a cross-sectional view schematically illustrating the manufacturing process in the method of manufacturing the bonded substrate according to the embodiment.

FIG. 23 is a cross-sectional view schematically illustrating the bonded substrate according to the embodiment, which is disposed on a second substrate.

### DETAILED DESCRIPTION

A manufacturing method according to an embodiment of the present disclosure, a bonded substrate obtained by the manufacturing method (hereinafter may be referred to as a “bonded substrate” according to an embodiment), and a light-emitting device (hereinafter may be referred to as a “light-emitting device according to an embodiment”) will be described below with reference to the accompanying drawings. In the following description, terms indicating specific directions and positions (for example, “upper”, “upward”, “lower”, “downward”, and other terms including these terms) are used as necessary. These terms are used to facilitate understanding of the present invention with reference to the drawings, and the technical scope of the present invention is not limited by the meaning of these terms. The same reference numerals appearing in a plurality of drawings refer to the same or similar portions or members.

Further, embodiments described below exemplify the bonded substrate, the light-emitting device, and the like to embody the technical ideas of the present invention, and the present invention is not limited to the following description. In addition, unless otherwise specified, the dimensions, materials, shapes, relative arrangements, and the like of components described below are not intended to limit the scope of the present invention thereto, but are described as examples. The contents described in one embodiment can be applied to other embodiments and modifications. The sizes, positional relationships, and the like of members illustrated in the drawings may be exaggerated for clearer illustration. Furthermore, in order to avoid excessive complication of the drawings, a schematic view in which some elements are not illustrated may be used, or an end view illustrating only a cut surface may be used as a cross-sectional view.

### Bonded Substrate According to Embodiment

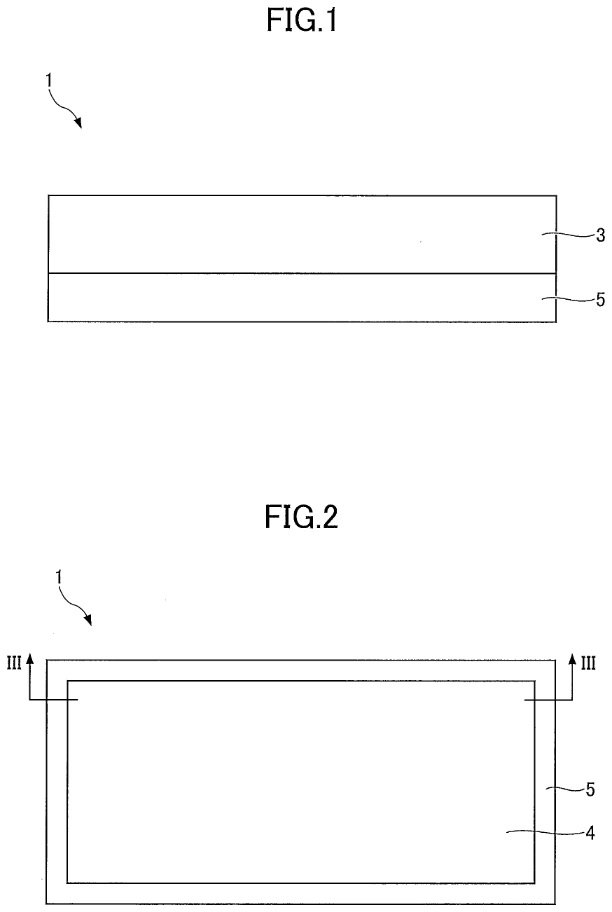

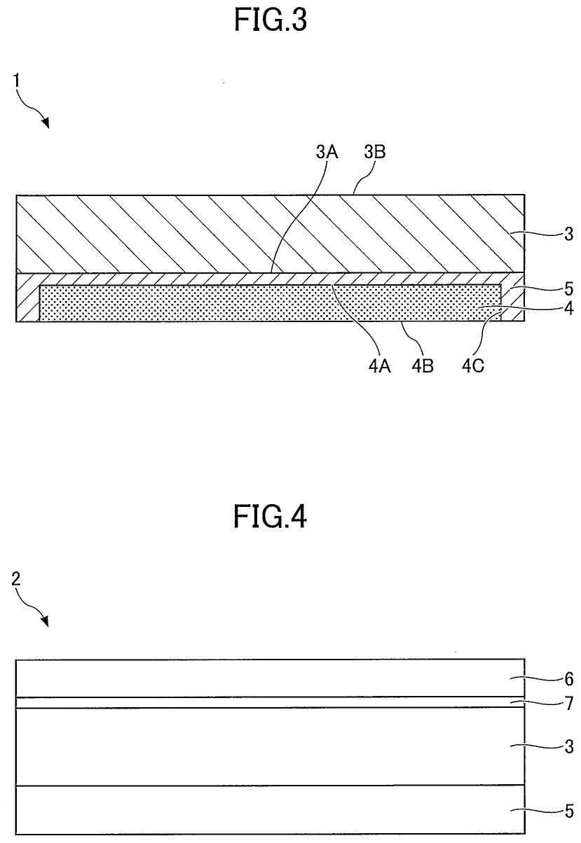

A bonded substrate 1, which is an example of a bonded substrate according to an embodiment, will be described with reference to FIG. 1 to FIG. 3. FIG. 1 is a side view schematically illustrating the bonded substrate 1. FIG. 2 is a bottom view schematically illustrating the bonded substrate 1. FIG. 3 is a cross-sectional view of the bonded substrate 1 taken through the line III-III of FIG. 2.

The bonded substrate 1 includes a metal plate 3, a first ceramic 4, and a first metal body 5. The first metal body 5 is disposed between a first surface 3A of the metal plate 3 and a first surface 4A of the first ceramic 4 and is disposed on 80% or more of a lateral surface 4C continuous with the first surface 4A of the first ceramic 4.

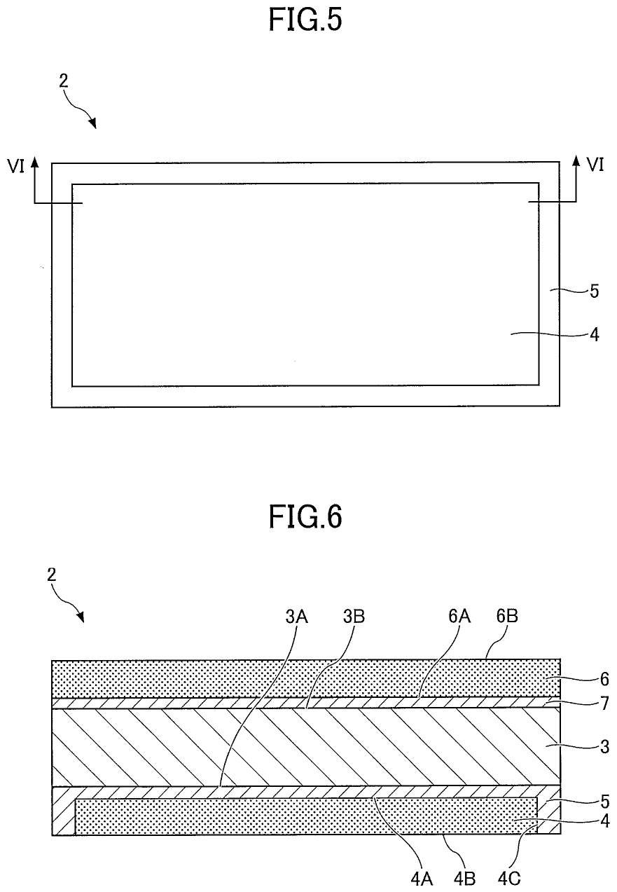

FIG. 4 to FIG. 6 are diagrams schematically illustrating a bonded substrate 2, which is another example of a bonded substrate according to an embodiment. FIG. 4 is a side view schematically illustrating the bonded substrate 2. FIG. 5 is a bottom view schematically illustrating the bonded substrate 2. FIG. 6 is a cross-sectional view of the bonded substrate 2 taken through the line VI-VI of FIG. 5.

As compared to the bonded substrate 1, the bonded substrate 2 further includes a second ceramic 6 and a second metal body 7. Specifically, the bonded substrate 2 includes a metal plate 3, a first ceramic 4, a first metal body 5, the second ceramic 6, and the second metal body 7. The first metal body 5 is disposed between a first surface 3A of the metal plate 3 and a first surface 4A of the first ceramic 4 and is disposed on 80% or more of a lateral surface 4C continuous with the first surface 4A of the first ceramic 4. The second metal body 7 is disposed between a second surface 3B of the metal plate 3 and a first surface 6A of the second ceramic 6.

Configurations of the bonded substrate 1 and the bonded substrate 2 will be described.

### Metal Plate

The metal plate 3 is a metal plate having a good heat dissipation property. The metal plate 3 has the first surface 3A and the second surface 3B opposite to the first surface 3A. The shape of the metal plate 3 in a plan view is, for example, a rectangular shape, but is not particularly limited.

The metal plate 3 is preferably a metal such as copper, nickel, aluminum, or molybdenum, a laminated plate made of two or more of these metals, or an alloy of two or more of these metals. The thickness of the metal plate 3 can be, for example, 100 μm or more and 700 μm or less, and is preferably 300 μm or more and 500 μm or less.

### First Ceramic

The first ceramic 4 is an insulating plate-shaped member. The first ceramic 4 has the first surface 4A, the second surface 4B opposite to the first surface 4A, and the lateral surface 4C other than the first surface 4A and the second surface 4B. The first ceramic 4 has, for example, a rectangular shape in a plan view, and the first metal body 5 is disposed on 80% or more, preferably 90% or more, and more preferably 100% of the lateral surface 4C of the first ceramic 4. The phrase “the first metal body 5 is disposed on 100% of the lateral surface 4C of the first ceramic 4” means that the first metal body 5 covers the entire periphery of the lateral surface 4C of the first ceramic 4. The thickness of the first ceramic 4 can be, for example, 50 μm or more and 300 μm or less, and is preferably 80 μm or more and 150 μm or less.

The first ceramic 4 is formed by being fired, and is not in a softened state before being fired. The first ceramic 4 can be formed by firing a ceramic, or can be a commercially available product or the like. The first ceramic 4 can be a ceramic including at least one of silicon nitride, aluminum nitride, boron nitride, magnesium oxide, or aluminum oxide, and preferably a ceramic including silicon nitride or aluminum nitride. The first ceramic 4 is preferably a nitride-based ceramic such as silicon nitride, aluminum nitride, or boron nitride; however, the first ceramic 4 can be an oxide-based ceramic such as aluminum oxide, silicon oxide, calcium oxide, or magnesium oxide. Further, for the first ceramic 4, beryllium oxide, silicon carbide, mullite, borosilicate glass, or the like can be used.

### First Metal Body

The first metal body 5 is a metal body obtained by firing a first bonding material 5a. The first metal body 5 is disposed between the first surface 3A of the metal plate 3 and the first surface 4A of the first ceramic 4 and is disposed on 80% or more of the lateral surface 4C continuous with the first surface 4A of the first ceramic 4. The first metal body 5 is preferably disposed on the entirety (100%) of the first surface 3A of the metal plate 3. The first metal body 5 is preferably disposed on the entirety (100%) of the lateral surface 4C of the first ceramic 4.

The main component of the first metal body 5 is a metal. The first metal body 5 includes at least one of Cu, Cr, Ni, Ag, Al, Zn, Sn, or an Ag—Cu alloy. The first metal body 5 preferably includes Ag and Cu, and the total content of Ag and Cu with respect to the entire first metal body 5 is preferably 80% by mass or more. The first metal body 5 preferably further includes an active metal element such as Ti, Ce, Zr, or Mg.

### Second Ceramic

The second ceramic 6 is an insulating plate-shaped member. The second ceramic 6 has the first surface 6A and a second surface 6B opposite to the first surface 6A. The shape of the second ceramic 6 in a plan view is, for example, a rectangular shape, but is not particularly limited. The matters that have been described with respect to the first ceramic 4 can be appropriately selected and applied to the material, the shape, and the like of the second ceramic 6.

### Second Metal Body

The second metal body 7 is a metal body obtained by firing a second bonding material 7a. The second metal body 7 is disposed between the second surface 3B of the metal plate 3 and the first surface 6A of the second ceramic 6. The second metal body 7 is preferably disposed on the entirety (100%) of the second surface 3B of the metal plate 3. The matters that have been described with respect to the first metal body 5 can be appropriately selected and applied to the components and the like of the second metal body 7.

In the bonded substrate 1, the thermal conductivity of the first metal body 5 is preferably higher than the thermal conductivity of the first ceramic 4. In the bonded substrate 2, the thermal conductivity of the first metal body 5 is preferably higher than the thermal conductivity of the first ceramic 4 and the thermal conductivity of the second ceramic 6.

In the bonded substrate 1, a lateral surface of the metal plate 3 and a lateral surface of the first metal body 5 are preferably coplanar with each other. Further, in the bonded substrate 2, a lateral surface of the metal plate 3, a lateral surface of the first metal body 5, and a lateral surface of the second ceramic 6 are preferably coplanar with each other.

In each of the bonded substrate 1 and the bonded substrate 2 having a configuration as described above, the first metal body 5 is disposed between the first surface 3A of the metal plate 3 and the first surface 4A of the first ceramic 4 and is disposed on 80% or more of the lateral surface 4C continuous with the first surface 4A of the first ceramic 4. Thus, the metal body is disposed on the bottom surface and a peripheral portion of each of the bonded substrate 1 and the bonded substrate 2. Accordingly, for example, in a case where the bonded substrate 1 or the bonded substrate 2 is mounted on another mounting substrate by using electrically-conductive paste, a fillet can be formed, and thus the bonded substrate 1 or the bonded substrate 2 having good thermal conductivity can be provided. That is, the electrically-conductive conductive paste such as silver paste wets the first metal body 5 disposed on the lateral surface 4C of the first ceramic 4 and a fillet is formed, and as a result, a heat conduction path that does not pass through the first ceramic 4 is formed. Accordingly, the thermal conductivity is further improved.

Further, in particular, each of the bonded substrate 1 and the bonded substrate 2 can reduce the occurrence of internal delamination and chipping of the first ceramic 4. Further, each of the bonded substrate 1 and the bonded substrate 2 can reduce warpage of the metal plate 3. The bonded substrate 2 can even further reduce warpage of the metal plate 3.

### Light-Emitting Device According to Embodiment

A light-emitting device 100 according to an embodiment includes the bonded substrate 1 or the bonded substrate 2 and a light-emitting element 30 disposed on the bonded substrate 1 or the bonded substrate 2. The light-emitting device 100 preferably further includes a covering member 70 disposed around the light-emitting element 30.

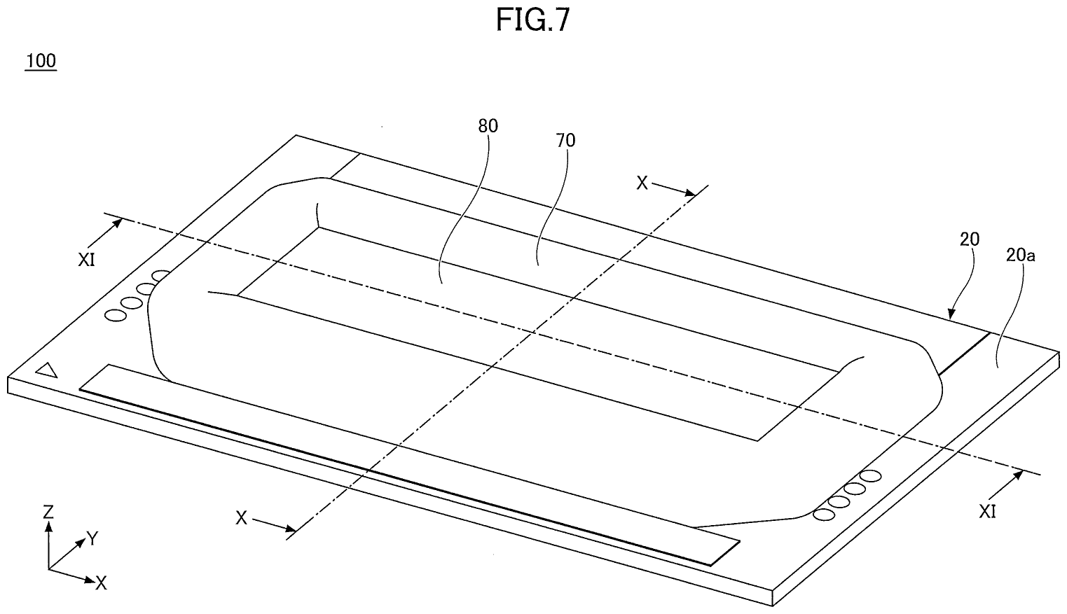

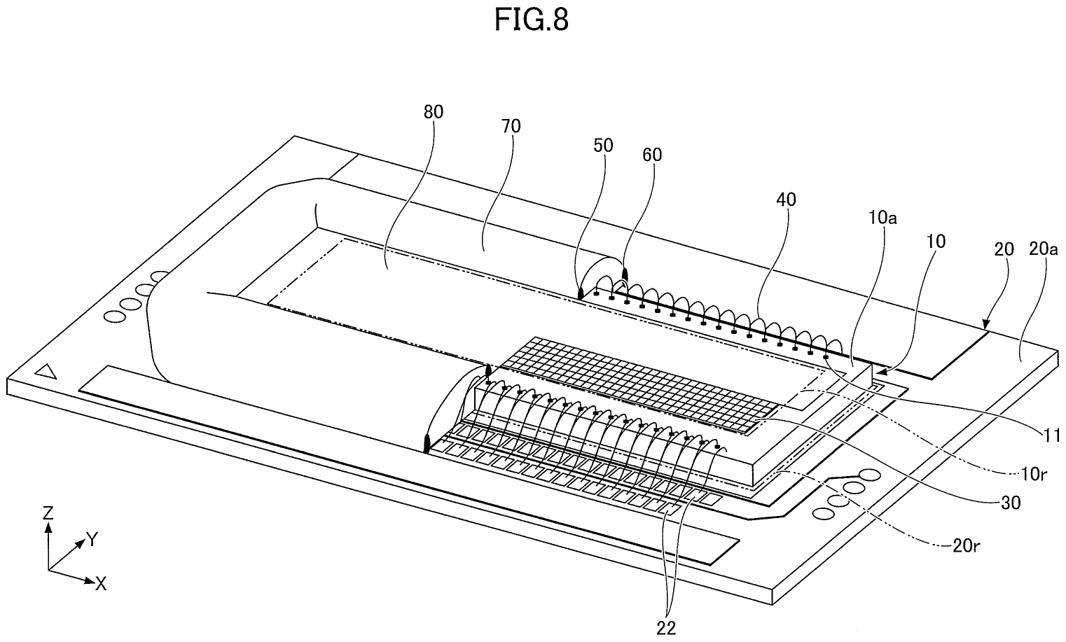

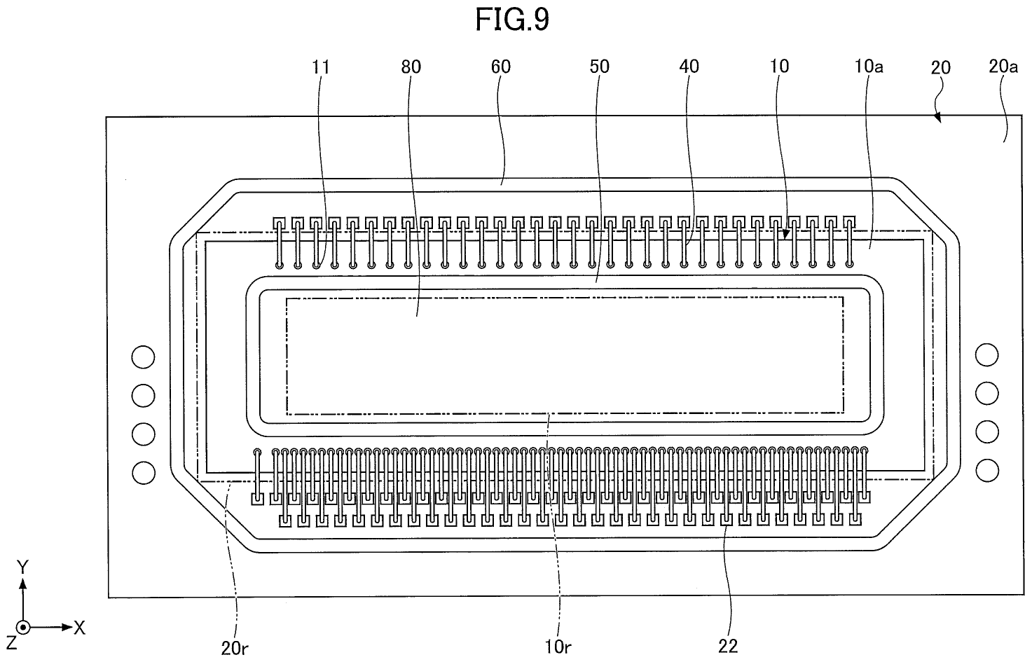

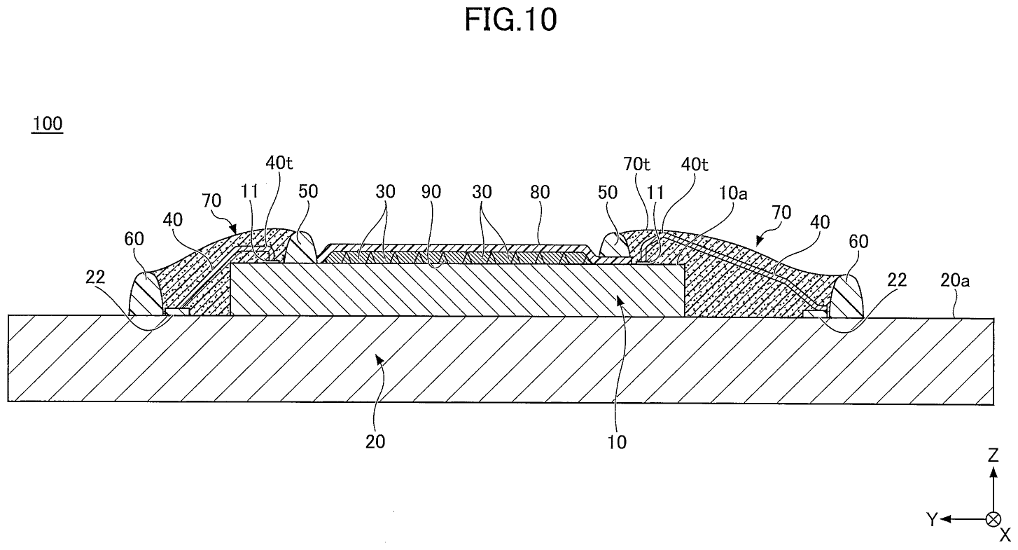

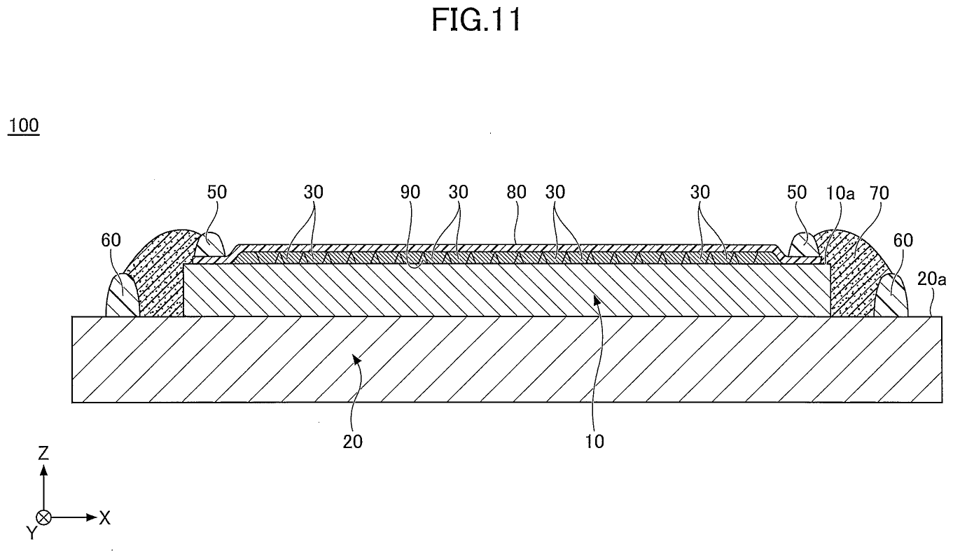

FIG. 7 is a perspective view schematically illustrating the light-emitting device according to the embodiment. FIG. 8 is a perspective view schematically illustrating the light-emitting device according to the embodiment, in which some components are not depicted. FIG. 9 is a plan view schematically illustrating the light-emitting device according to the embodiment. FIG. 10 is a cross-sectional view of the light-emitting device taken through the line X-X of FIG. 7. FIG. 11 is a cross-sectional view of the light-emitting device taken through the line XI-XI of FIG. 7.

As illustrated in FIG. 7 to FIG. 11, the light-emitting device 100 according to the embodiment includes a first substrate 10, which is a bonded substrate according to the embodiment, a second substrate 20, the light-emitting element 30, a wire 40, a first frame part 50, a second frame part 60, and the covering member 70.

The light-emitting device 100 can include a light-transmissive member 80 that covers the upper surface of a plurality of light-emitting elements 30. The light-emitting device 100 can include a reflective member 90 that exposes the upper surfaces of the plurality of light-emitting elements 30 and covers the lateral surfaces of the plurality of light-emitting elements 30 in an element placement region 10r of an upper surface 10a of the first substrate 10. In the following, an example in which the light-emitting device 100 includes the light-transmissive member 80 and the reflective member 90 will be described.

In FIG. 8, for convenience of illustration, a portion of each of the covering member 70, the first frame part 50, the second frame part 60, and the light-transmissive member 80 is not depicted so as to visualize a portion of each of the wire 40 and the light-emitting elements 30. In FIG. 9, for convenience of illustration, the covering member 70 is not depicted so as to visualize the wire 40, the first frame part 50, the second frame part 60, and the like.

The first substrate 10 includes the element placement region 10r and a first terminal 11 on the upper surface 10a. The first terminal 11 is located outward relative to the element placement region 10r. The light-emitting elements 30 are arranged in the element placement region 10r of the first substrate 10. The second substrate 20 includes a substrate placement region 20r and a second terminal 22 on an upper surface 20a. The first substrate 10 is placed in the substrate placement region 20r, and the second terminal 22 is located outward relative to the substrate placement region 20r.

The first substrate 10 is placed in the substrate placement region 20r of the second substrate 20. The first frame part 50 surrounding the element placement region 10r is located inward relative to the first terminal 11 on the upper surface 10a of the first substrate 10. The second frame part 60 surrounding the first substrate 10 is located outward relative to the second terminal 22 on the upper surface 20a of the second substrate 20.

The first terminal 11 of the first substrate 10 is electrically connected to the second terminal 22 of the second substrate 20 by the wire 40. The first terminal 11, the second terminal 22, and the wire 40 are located between the first frame part 50 and the second frame part 60 in a plan view. The first terminal 11, the second terminal 22, and the wire 40 are covered by the covering member 70.

### Light-Emitting Element

A light-emitting element 30 has, for example, a substantially rectangular shape in a plan view. The light-emitting element 30 can have, for example, a square shape with a side of 40 μm or more and 100 μm or less in a plan view. The light-emitting element 30 includes a semiconductor stack and positive and negative electrodes disposed on the surface of the semiconductor stack. The light-emitting element 30 includes the positive and negative electrodes on the same surface, and is flip-chip mounted on the first substrate 10 with the surface on which the electrodes are disposed serving as a lower surface. In this case, the upper surface opposite to the surface on which the electrodes are disposed serves as a main light extraction surface of the light-emitting element 30. In the light-emitting device 100, a plurality of light-emitting elements 30 are arranged on the first substrate 10 at predetermined intervals in the row and column directions. The size and the number of light-emitting elements 30 to be used can be appropriately selected in accordance with the configuration of a light-emitting module to be obtained. It is preferable to arrange a larger number of smaller light-emitting elements 30 at a high density. Accordingly, an irradiation range of light emitted from the light-emitting device 100 can be controlled with a larger number of divisions. The light-emitting device 100 having such a configuration can be used as a light source of a high-resolution lighting system. For example, the number of light-emitting elements 30 included in the light-emitting device 100 can be 1,000 or more and 20,000 or less.

The light-emitting element 30 can be selected from one having a given wavelength. For example, as a light-emitting element 30 that emits blue light and green light, a light-emitting element using a nitride semiconductor (InₓAl_{y}Ga_{1-x-y}N, 0≤x, 0≤y, x+y≤1) can be selected. As a light-emitting element 30 that emits red light, a semiconductor represented by GaAlAs or AlInGaP can be used. Further, a semiconductor light-emitting element formed of any other material can be used. The composition and the emission color of a light-emitting element 30 to be used can be appropriately selected according to the purpose.

The light-emitting element 30 is bonded to wiring disposed in the element placement region 10r by using an electrically-conductive bonding member. If the light-emitting element 30 is flip-chip mounted on the first substrate 10, a bump made of a metal material such as Au, Ag, Cu, or Al can be used as the bonding member. Further, as the bonding member, solder such as an AuSn-based alloy or an Sn-based lead-free solder can be used. Further, as the bonding member, an electrically-conductive adhesive material in which electrically-conductive particles such as metal particles are contained in a resin can be used. The light-emitting element 30 and the first substrate 10 can be bonded by plating. Examples of a plating material include Cu. Further, the electrodes of the light-emitting element 30 and the wiring of the first substrate 10 can directly contact each other without the bonding member interposed therebetween.

### Covering Member

The covering member 70 is a light-shielding member covering the wire 40, and is located outward relative to the element placement region 10r. The covering member 70 is disposed in a frame shape in a plan view so as to cover the wire 40 and surround the element placement region 10r, for example. The covering member 70 is disposed in contact with the first frame part 50 and the second frame part 60.

The covering member 70 is separated from the light-emitting element 30 in a plan view. The distance between the light-emitting element 30 and the covering member 70 can be 100 μm or more and 500 μm or less. Further, in a plan view, the width of the covering member 70 located on the long side of the first substrate 10 is wider than the width of the covering member 70 located on the short side of the first substrate 10. The covering member 70 is preferably disposed such that the height of the covering member 70 (that is, the distance from the upper surface 20a of the second substrate 20 to the upper surface of the covering member 70) is the highest directly above a top 40t of the wire 40. In other words, the covering member 70 is preferably disposed such that a top 70t of the covering member 70 overlaps the top 40t of the wire 40. Further, the position of the top 70t of the covering member 70 is preferably located above the top of the first frame part 50. In the present specification, the widths of the covering member 70 located on the long side and the short side of the first substrate 10 refer to the widths in directions orthogonal to the short side and the long side of the first substrate 10 in a plan view. Further, the height of the covering member 70 refers to the distance from the upper surface of the second substrate 20 to the upper surface of the covering member 70.

Examples of the covering member 70 include a resin containing a filler having a light shielding property. Examples of the resin as a base material include a silicone resin, a modified silicone resin, an epoxy resin, a modified epoxy resin, and an acrylic resin. As the filler having a light shielding property, a light absorbing material such as a pigment, carbon black, titanium black, or graphite; or a light reflective substance such as titanium oxide, aluminum oxide, zinc oxide, barium carbonate, barium sulfate, boron nitride, aluminum nitride, or a glass filler can be suitably used. Specifically, examples of the external color of the covering member 70 include white having good light reflectivity, black having good light absorbency, and gray having light reflectivity and light absorbency. The covering member 70 can be a member in which a plurality of resin layers are laminated. The covering member 70 is preferably formed of a white resin having light reflectivity on at least the outermost surface thereof, from the viewpoint of suppressing deterioration of the resin due to light absorption.

The light-emitting device 100 having the above-described configuration can be used as a light source of an in-vehicle headlight as an example. In such a case, a configuration in which light is emitted from a light source to the outside through a lens is adopted. The light-emitting device 100 turns on the light-emitting element 30 via an external power switch. The light-emitting device 100 is configured to individually drive some of or all of preset light-emitting elements 30.

### Methods of Manufacturing Bonded Substrates According to Embodiments

A method of manufacturing a bonded substrate according to a first embodiment includes: disposing a first bonding member in a recess and on a first surface of a first ceramic plate, the first ceramic plate having the first surface, the recess recessed from the first surface, and a second surface opposite to the first surface; disposing a metal plate such that the first surface of the first ceramic plate and a first surface of the metal plate face each other with the first bonding member interposed therebetween; firing the first ceramic plate, the first bonding member, and the metal plate; polishing or grinding the second surface of the first ceramic plate in a stack in which a first metal body is obtained by the firing of the first bonding member, and the metal plate and the first ceramic plate are bonded together by the first metal body; and in the stack in which a portion of the first metal body is exposed through the first ceramic plate by the polishing or the grinding of the second surface of the first ceramic plate, cutting the stack from the metal plate to the first ceramic plate through the first metal body disposed in the recess. In this manner, the bonded substrate 1 according to the first embodiment can be suitably manufactured.

In addition to the disposing of the first bonding member and the disposing of the disposing the metal plate, a method of manufacturing a bonded substrate according to a second embodiment further includes: before the firing of the first ceramic plate, the first bonding member, and the metal plate, disposing a second ceramic plate such that a first surface of the second ceramic plate and a second surface opposite to the first surface of the metal plate face each other with a second bonding material interposed therebetween; in the firing of the first ceramic plate, the first bonding member, and the metal plate, firing the second bonding material and the second ceramic plate together with the first ceramic plate, the first bonding member, and the metal plate; in the polishing or the grinding of the second surface of the first ceramic plate, polishing or grinding the second surface of the first ceramic plate in a stack in which a second metal body is obtained by the firing of the second bonding material, and the metal plate and the second ceramic plate are bonded together by the second metal body; and in the cutting of the stack, cutting the stack, in which the second ceramic plate, the second metal body, the metal plate, the first metal body, and the first ceramic plate are bonded together, from the second ceramic plate toward the metal plate and the first ceramic plate. In this manner, the bonded substrate 2 according to the second embodiment can be suitably manufactured.

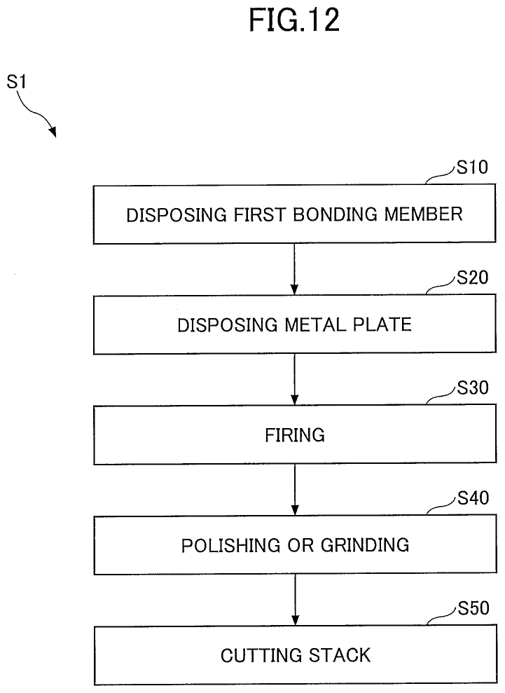

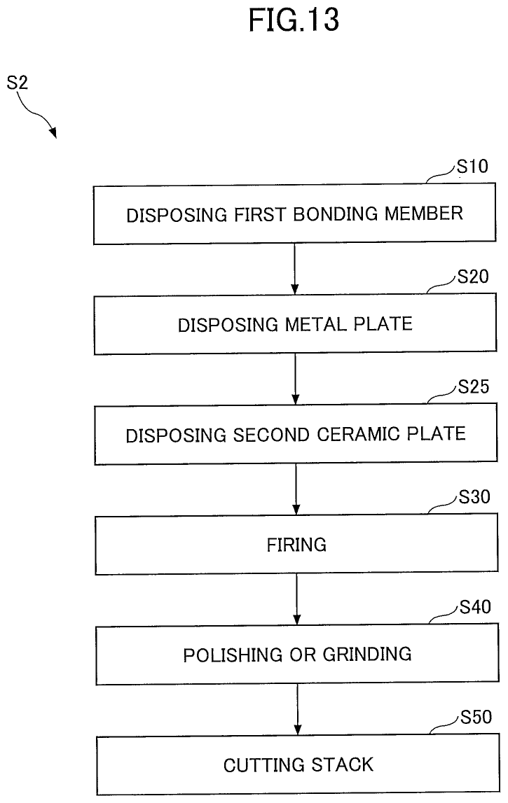

FIG. 12 is a flowchart illustrating a method S1 of manufacturing the bonded substrate according to the first embodiment. FIG. 13 is a flowchart illustrating a method S2 of manufacturing the bonded substrate according to the second embodiment.

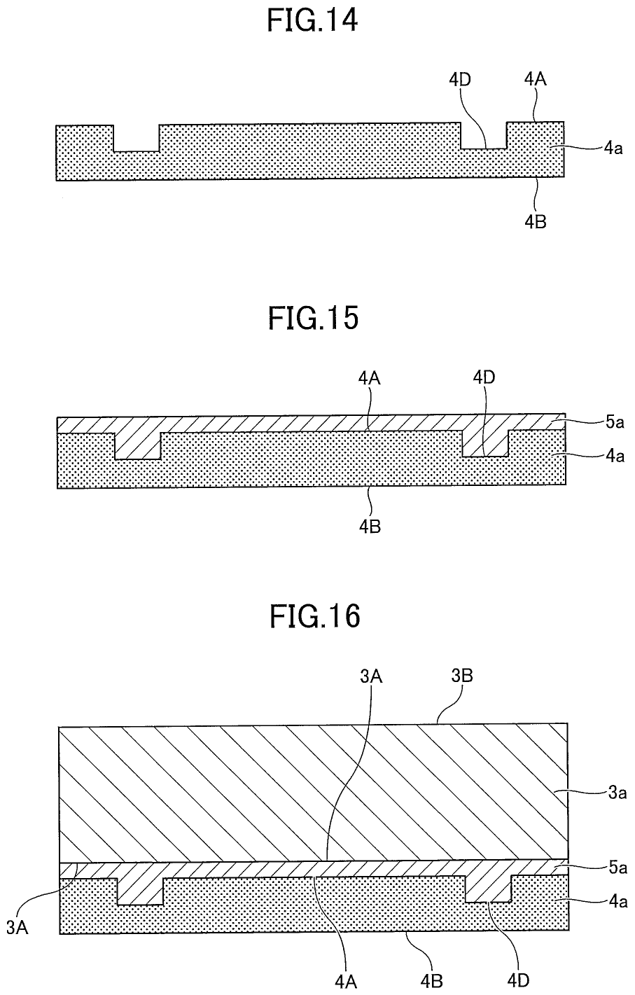

FIG. 14 to FIG. 22 are diagrams schematically illustrating an example of a manufacturing process in a method of manufacturing a light-emitting module according to an embodiment. Specifically, FIG. 14 to FIG. 22 are cross-sectional views illustrating a manufacturing process in a method of manufacturing a bonded substrate according to the first embodiment or the second embodiment. In the description of the manufacturing method, preparing a member is not limited to manufacturing a member, and includes acquiring a member such as purchasing a member or receiving a member.

### Disposing First Bonding Member

In step S10 of disposing a first bonding member, a first bonding material 5a is disposed in a recess 4D and on a first surface 4A of a first ceramic plate 4a having the first surface 4A, the recess 4D recessed from the first surface 4A, and a second surface 4B opposite to the first surface 4A (see FIG. 14 and FIG. 15).

The first ceramic plate 4a is formed by firing a predetermined green sheet or the like or by solidifying and firing a ceramic powder. The recess 4D is preferably formed by being irradiated with laser after a ceramic is fired, or is preferably formed by polishing or grinding the ceramic with a dicer or the like. Alternatively, the recess 4D can be formed by forming a recess in an unfired green sheet or the like and firing the green sheet or the like. The first ceramic plate 4a can be formed by stacking a plurality of predetermined green sheets. An inner wall of the recess 4D serves as a lateral surface 4C of a first ceramic 4.

FIG. 14 is a cross-sectional view schematically illustrating the first ceramic plate 4a having the first surface 4A, the recess 4D recessed from the first surface 4A, and the second surface 4B opposite to the first surface 4A. For simplification, the first ceramic plate 4a that includes one first ceramic 4 in the widthwise direction of FIG. 14 is illustrated; however, the first ceramic plate 4a can include an aggregate of a plurality of first ceramics 4 in the widthwise direction and the depth direction of FIG. 14. A recess 4D can be appropriately formed such that the first ceramic 4 has an intended shape in a plan view in an bonded substrate. For example, by using a first ceramic plate 4a in which a recess 4D is has a grid pattern in a top view, a large number of bonded substrates can be manufactured.

In the first ceramic plate 4a having the recess 4D, the recess 4D can be formed by processing such as laser processing or dicing. The recess 4D can have a quadrangular shape or a tapered shape in a cross-sectional view. The width of the recess 4D can be appropriately selected according to the accuracy of polishing or grinding or the like, and can be, for example, 50 μm or more and 300 μm or less. The depth of the recess 4D can be, for example, 50 μm or more and 300 μm or less, and is preferably 80 μm or more and 150 μm or less.

Next, as illustrated in FIG. 15, the first bonding material 5a is disposed in the recess 4D and on the first surface 4A of the first ceramic plate 4a. The first bonding material 5a can be disposed by, for example, screen-printing.

The first bonding material 5a is a member including a metal and having fluidity, and is preferably an active metal brazing material. The first bonding material 5a can be applied so as to be in close contact with the inside of the recess 4D and with the first surface 4A. In this example, the first bonding material 5 is disposed such that the first bonding material 5 fills the recess 4D and is further applied to the first surface 4A without causing unevenness in the surface of the first bonding material 5a. The first bonding material 5a is preferably disposed so as to have a uniform thickness from the first surface 4A. A first metal body 5 is obtained by firing the first bonding material 5a.

The first bonding material 5a includes at least one selected from the group consisting of Cu, Cr, Ni, Ag, Al, Zn, Sn, and an Ag—Cu alloy. Among them, an Ag—Cu alloy, which can be fired at a relatively low temperature of 780° C. or more and 850° C. or less, is preferable. Further, at least one of Cu or Ag, which has a high electrical conductivity, is preferable.

The first bonding material 5a preferably includes an active metal powder. The active metal powder can include at least one selected from the group consisting of TiH₂, CeH₂, ZrH₂, and MgH₂. Among them, TiH₂ is preferable. If the first bonding material 5a includes TiH₂, TiH₂ reacts with nitride contained in the first ceramic plate 4a, and a metal compound layer that becomes a reaction layer such as TiN is formed at an interface with the first ceramic plate 4a. As a result, the adhesion between the first metal body 5, obtained by firing the first bonding material 5a, and the first ceramic plate 4a can be improved, and the first metal body 5 can firmly adhere to the inside of the recess 4D and to the first surface 4A.

The first bonding material 5a can include an organic binder. The viscosity of the first bonding material 5a can be adjusted according to the type and the amount of the organic binder. Examples of the organic binder include a solvent generally used as electrically-conductive paste, and a resin material such as acrylic, epoxy, urethane, ethyl cellulose, silicone, phenol, polyimide, polyurethane, melamine, and urea. The organic binder is decomposed, volatilized, and removed during firing, which will be described later. The first bonding material 5a can include an inorganic filler other than metals. When the first bonding material 5a includes the inorganic filler, volume shrinkage when the first bonding material 5a is fired can be reduced. As the inorganic filler, AlN, Si₃N₄, or the like can be used, for example.

With respect to the total amount of the first bonding material 5a, the total content of silver and copper is preferably 80% by mass or more, the content of TiH₂ as an active metal powder is preferably 0.5% by mass or more and 10% by mass or less, the content of the organic binder is preferably 0.1% by mass or more and 10% by mass or less, and the content of the inorganic filler is preferably 1% by mass or more and 20% by mass or less.

### Disposing Metal Plate

In step S20 of disposing a metal plate, a metal plate 3a is disposed such that the first surface 4A of the first ceramic plate 4a and a first surface 3A of the metal plate 3a face each other with the first bonding material 5a interposed therebetween (see FIG. 16). Accordingly, an unfired stack for manufacturing the bonded substrate 1 can be obtained. The metal plate 3a can be an aggregate of a plurality of metal plates 3. In such a case, the aggregate is cut such that the plurality of metal plates 3 are separated as described below.

### Disposing Second Ceramic Plate

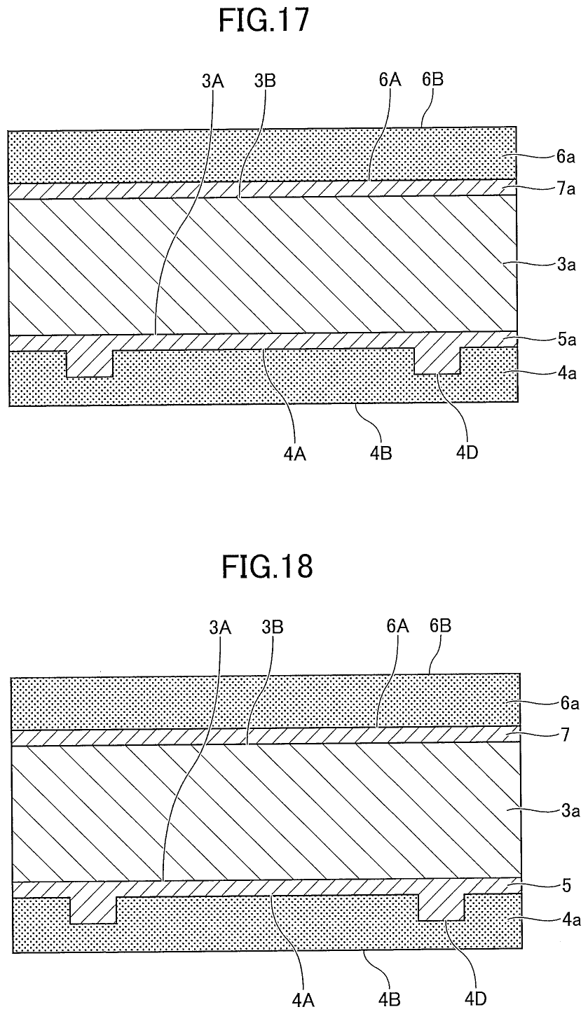

In order to manufacture the bonded substrate 2 including a second ceramic 6 and a second metal body 7 in addition to the configuration of the bonded substrate 1 by using the method of manufacturing the bonded substrate 2 according to the second embodiment, step S25 of disposing a second ceramic plate 6a (see FIG. 17) is further included. Accordingly, an unfired stack for manufacturing the bonded substrate 2 can be obtained.

In step S25 of disposing the second ceramic plate 6a, before firing, the second ceramic plate 6a is disposed such that a first surface 6A of the second ceramic plate 6a and the second surface 3B of the metal plate 3a face each other with the second bonding material 7a interposed therebetween.

The second bonding material 7a is a member including a metal and having fluidity, and is preferably an active metal brazing material. The second bonding material 7a can be applied to the first surface 6A of the second ceramic plate 6a or can be applied to the second surface 3B of the metal plate 3a. The surface to which the second bonding material 7a is applied can be appropriately selected.

The matters that have been described with respect to the first bonding material 5a can be appropriately selected and applied to the components and the like of the second bonding material 7a.

The first bonding material 5a disposed in the recess 4D and on the first surface 4A of the first ceramic plate 4a can be the same as or different from the second bonding material 7a disposed on the first surface 6A of the second ceramic plate 6a, and is preferably the same as the second bonding material 7a. It is preferable that the first bonding material 5a has a lower content ratio of an organic solvent and a lower volume shrinkage rate associated with drying during firing than those of the second bonding material 7a.

### Firing

Next, in step S30 of firing, the first bonding material 5a, the second bonding material 7a, and the like are fired to obtain a stack including the first metal body 5, the second metal body 7, and the like (see FIG. 18).

In step S30 of firing, the first bonding material 5a is fired such that the first ceramic plate 4a and the metal plate 3a are bonded together, and the first metal body 5 is obtained by firing the first bonding material 5a.

Further, in the method of manufacturing the bonded substrate according to the second embodiment, the first bonding material 5a is fired so as to bond the first ceramic plate 4a and the metal plate 3a together, and the second bonding material 7a is fired so as to bond the second ceramic plate 6a and the metal plate 3a together. FIG. 17 and FIG. 18 are diagrams respectively illustrating the stack before being fired and the stack after being fired by the method of manufacturing the bonded substrate according to the second embodiment.

The firing temperature can be 700° C. or more and 1,200° C. or less, and is preferably 800° C. or more and 1,100° C. or less. The firing atmosphere is preferably a vacuum atmosphere of 10⁻⁵ Pa or less or an Ar atmosphere of 99.9% or more.

The organic solvents are decomposed, volatilized, and removed by firing the first bonding material 5a and the second bonding material 7a. The removal of the organic solvents causes the volume of the first metal body 5 and the volume of the second metal body 7 to shrink as compared to the volume of the first bonding material 5a and the volume of the second bonding material 7a. In order to prevent the first metal body 5 and the second metal body 7 from being deformed or peeled off from the first ceramic plate 4a and the second ceramic plate 6a and to reduce warpage of the first ceramic plate 4a and the second ceramic plate 6a due to the shrinkage in the obtained fired stack, firing is preferably performed under a load. The load can be, for example, 0.001 kg/cm² or more and 2 kg/cm² or less in the stacking direction such that the load is uniformly applied to the unfired stack.

In addition, at the time of firing, metal compound layers, which include reaction products of nonmetal elements contained in the first ceramic plate 4a and the second ceramic plate 6a with active metal elements contained in the first bonding material 5a and the second bonding material 7a, are formed. That is, the first metal body 5 has a metal compound layer changed from an active metal powder at the interface between the first ceramic plate 4a and the first metal body 5. If the stack includes the second metal body 7, the second metal body 7 has a metal compound layer changed from an active metal powder at the interface between the second ceramic plate 6a and the second metal body 7. The metal compound layers preferably contain TiN, which is a reaction product of nitride contained in the first ceramic plate 4a and the second ceramic plate 6a with TiH₂ contained in the active metal powders of the first bonding material 5a and the second bonding material 7a. When the first metal body 5 has the metal compound layer at the interface between the first ceramic plate 4a and the first metal body 5, and the second metal body 7 has the metal compound layer at the interface between the second ceramic plate 6a and the second metal body 7, the bonding reliability can be increased.

### Polishing or Grinding

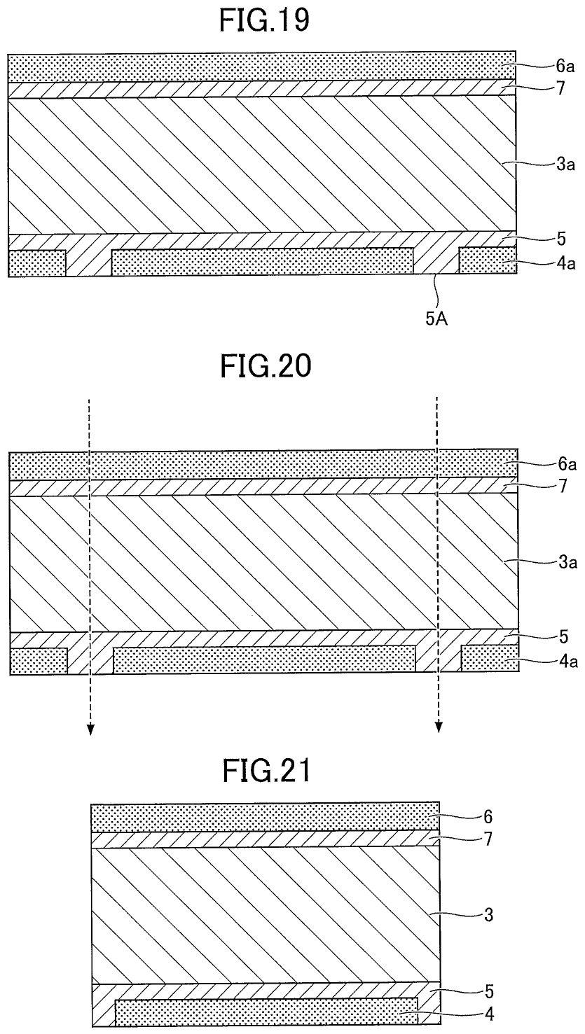

Next, in step S40 of polishing or grinding, in the obtained fired stack (see FIG. 18), the second surface 4B of the first ceramic plate 4a is polished or ground. By polishing or grinding the second surface 4B of the first ceramic plate 4a, a stack in which a portion of the first metal body 5 is exposed through the first ceramic plate 4a is obtained (see FIG. 19).

In step S40 of polishing or grinding, in the stack in which the first metal body 5 is obtained by firing the first bonding material 5a, and the metal plate 3a and the first ceramic plate 4a are bonded together by the first metal body 5, the second surface 4B of the first ceramic plate 4a is polished or ground.

In the method of manufacturing the bonded substrate according to the second embodiment, in step S40 of polishing or grinding, the second surface 4B of the first ceramic plate 4a are polished or ground in the stack in which the second metal body 7 is further obtained by firing the second bonding material 7a, and the first ceramic plate 4a and the metal plate 3a are bonded together by the second metal body 7. Further, the second surface 6B of the second ceramic plate 6a can be polished or ground.

It is preferable that the second surface 4B of the first ceramic plate 4a and the first metal body 5 are polished or ground such that the second surface 4B of the first ceramic plate 4a and an exposed surface of the first metal body 5 are coplanar with each other.

### Plating

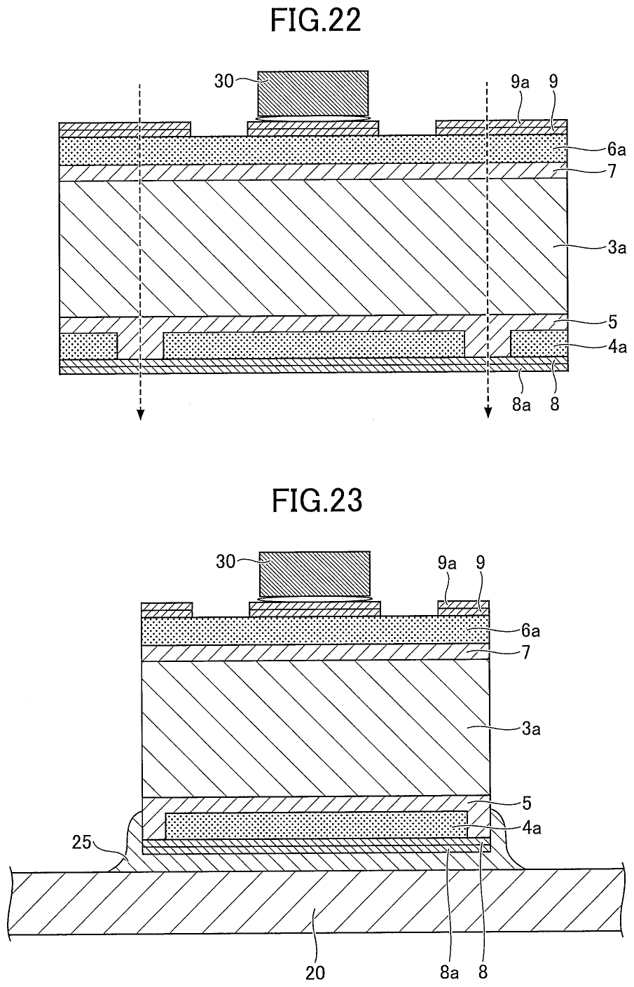

After polishing or grinding and before cutting, optionally, the obtained polished or ground stack (see FIG. 19) can be further subjected to step S45 of plating (see FIG. 22).

In step S45 of plating, after polishing or grinding and before cutting, a first electrically-conductive member 8 is disposed on the second surface 4B of the first ceramic plate 4a and an exposed surface 5A of the first metal body 5, and plating 8a is applied to the first electrically-conductive member 8 (see FIG. 22).

The first electrically-conductive member 8 can be formed by sputtering of a metal such as copper. The plating 8a can be formed by electroless plating. As a result, plated wiring can be formed. The metal sputtering or plating can be performed through a mask.

Further, the method of manufacturing the bonded substrate according to the second embodiment preferably includes, after polishing or grinding and before cutting, disposing a second electrically-conductive member 9 on the second surface 6B of the second ceramic plate 6a. Further, plating 9a can be applied to the second electrically-conductive member 9 (see FIG. 22).

### Cutting Stack

In step S50 of cutting a stack, the obtained polished or ground stack (see FIG. 19) is cut (see FIG. 20) such that an individual bonded substrate (see FIG. 21) is obtained. The stack before being cut is preferably an aggregate of a plurality of bonded substrates.

In the method of manufacturing the bonded substrate according to the second embodiment, in step S50 of cutting the stack, the stack, in which a portion of the first metal body 5 is exposed through the first ceramic plate 4a by polishing or grinding the second surface of the first ceramic plate, is cut from the metal plate 3a toward the first ceramic plate 4a through the portion of the first metal body 5 disposed in the recess 4D (see a dashed-line arrow in FIG. 20).

In the method of manufacturing the bonded substrate according to the second embodiment, in step S50 of cutting the stack, the stack, in which the second ceramic plate 6a, the second metal body 7, the metal plate 3a, the first metal body 5, and the first ceramic plate 4a are bonded together, is cut from the second ceramic plate 6a toward the metal plate 3a and the first ceramic plate 4a (see the dashed-line arrow in FIG. 20).

The stack is preferably cut by at least one of irradiation with a water jet laser or dicing with a dicer. The stack is cut in the stacking direction of the stack through the first metal body 5 disposed in the recess 4D of the first ceramic plate 4a and along the shape of the recess 4D formed in advance.

The method of manufacturing the bonded substrate having the above-described configuration can reduce the occurrence of delamination between the first ceramic 4 and the metal plate 3 and chipping of the first ceramic 4, and can manufacture the bonded substrate in which the delamination and chipping is reduced.

The inventors of the present application have found the following problems in the related-art technique through research. That is, the inventors have found problems in that, when a related-art large-sized substrate in which a copper plate is sandwiched between two ceramic plates via active metal brazing materials is used and is cut from the copper plate side toward a ceramic plate by irradiation with a water jet laser or dicing with a dicer, delamination occurs between the ceramic plate and the copper plate and also chipping occurs in the ceramic plate. In the method of manufacturing the bonded substrate according to the first or second embodiment, a portion of the first ceramic plate 4a located at a cut position is removed in advance and replaced with a portion of the first metal body 5. In this manner, the problems in the related art technique can be solved, and the bonded substrate in which the occurrence of delamination and chipping is reduced can be manufactured.

Further, in the method of manufacturing the bonded substrate according to the first or second embodiment, the bonded substrate having good thermal conductivity can be manufactured. That is, in the manufactured bonded substrate, the first metal body 5 is disposed between the first surface 3A of the metal plate 3 and the first surface 4A of the first ceramic 4 and is disposed on 80% or more of the lateral surface 4C continuous with the first surface 4A of the first ceramic 4, and thus the first metal body 5 is disposed on the bottom surface and a peripheral portion of the bonded substrate. Accordingly, for example, in a case where the bonded substrate is mounted on another mounting substrate by using electrically-conductive paste, a fillet can be formed, and thus the bonded substrate having good thermal conductivity can be manufactured.

### Method of Manufacturing Light-Emitting Device According to Embodiment

A method of manufacturing a light-emitting device according to an embodiment includes manufacturing a bonded substrate by the manufacturing method S1 or S2 according to the above-described first or second embodiment, and disposing a light-emitting element on the bonded substrate.

### Disposing Light-Emitting Element

In step S3 of disposing a light-emitting element, a light-emitting element 30 can be disposed on the bonded substrate by a publicly-known method that can be appropriately selected. For example, the light-emitting element can be disposed after the bonded substrate is manufactured, or can be disposed in the process of manufacturing the bonded substrate.

If the light-emitting element is disposed in the process of manufacturing the bonded substrate, for example, as illustrated in FIG. 22, after polishing or grinding and before cutting, the light-emitting element 30 can be disposed on the stack with an electrically-conductive member interposed therebetween, after the second electrically-conductive member 9 is disposed on the second surface 6B of the second ceramic plate 6a and the plating 9a is further applied to the second electrically-conductive member 9. Thereafter, the stack is cut in the direction indicated by the dashed-line arrow in FIG. 22 to obtain an individual bonded substrate.

As illustrated in FIG. 23, if the bonded substrate according to the first or second embodiment is mounted on the second substrate 20 by using electrically-conductive paste 25, the first metal body 5 is disposed between the first surface of the metal plate 3 and the first surface of the first ceramic 4 and is disposed on 80% or more of the lateral surface 4C continuous with the first surface 4A of the first ceramic 4. Thus, the first metal body 5 is disposed on the bottom surface and a peripheral portion of the bonded substrate. Accordingly, a fillet can be formed, and thus the bonded substrate having good thermal conductivity can be manufactured.

According to an embodiment of the present disclosure, a bonded substrate that reduces the occurrence of internal delamination and chipping and has good thermal conductivity, and a method of manufacturing the bonded substrate can be provided.

Although embodiments have been described in detail above, the above-described embodiments are non-limiting examples, and various modifications and substitutions can be made to the above-described embodiments without departing from the scope described in the claims.

1. A bonded substrate comprising:
a metal plate;
a first ceramic; and
a first metal body disposed between a first surface of the metal plate and a first surface of the first ceramic and disposed on 80% or more of a lateral surface continuous with the first surface of the first ceramic.

2. The bonded substrate according to claim 1, further comprising:
a second ceramic; and
a second metal body disposed between a second surface opposite to the first surface of the metal plate and a first surface of the second ceramic.

3. The bonded substrate according to claim 1, wherein
the first metal body contains silver and copper, and
a total content of the silver and the copper with respect to an entirety of the first metal body is 80% by mass or more.

4. The bonded substrate according to claim 1, wherein a thermal conductivity of the first metal body is higher than a thermal conductivity of the first ceramic.

5. The bonded substrate according to claim 1, wherein the first metal body is disposed on an entirety of the lateral surface of the first ceramic.

6. The bonded substrate according to claim 1, wherein the first metal body is disposed on an entirety of the first surface of the metal plate.

7. The bonded substrate according to claim 1, wherein a lateral surface of the metal plate and a lateral surface of the first metal body are coplanar with each other.

8. A light-emitting device comprising:
the bonded substrate of claim 1; and
a light-emitting element disposed on the bonded substrate.

9. The light-emitting device according to claim 8, further comprising a covering member disposed around the light-emitting element.

10. A method of manufacturing a bonded substrate, the method comprising:
disposing a first bonding member in a recess and on a first surface of a first ceramic plate, the first ceramic plate having the first surface, the recess recessed from the first surface, and a second surface opposite to the first surface;
disposing a metal plate such that the first surface of the first ceramic plate and a first surface of the metal plate face each other with the first bonding member interposed therebetween;
firing the first ceramic plate, the first bonding member, and the metal plate;
polishing or grinding the second surface of the first ceramic plate in a stack in which a first metal body is obtained by the firing of the first bonding member, and the metal plate and the first ceramic plate are bonded together by the first metal body; and
in the stack in which a portion of the first metal body is exposed through the first ceramic plate by the polishing or the grinding of the second surface of the first ceramic plate, cutting the stack from the metal plate to the first ceramic plate through the first metal body disposed in the recess.

11. The method of manufacturing the bonded substrate according to claim 10, further comprising:
before the firing of the first ceramic plate, the first bonding member, and the metal plate, disposing a second ceramic plate such that a first surface of the second ceramic plate and a second surface opposite to the first surface of the metal plate face each other with a second bonding material interposed therebetween;
in the firing of the first ceramic plate, the first bonding member, and the metal plate, firing the second bonding material and the second ceramic plate together with the first ceramic plate, the first bonding member, and the metal plate;
in the polishing or the grinding of the second surface of the first ceramic plate, polishing or grinding the second surface of the first ceramic plate in a stack in which a second metal body is obtained by the firing of the second bonding material, and the metal plate and the second ceramic plate are bonded together by the second metal body; and
in the cutting of the stack, cutting the stack, in which the second ceramic plate, the second metal body, the metal plate, the first metal body, and the first ceramic plate are bonded together, from the second ceramic plate toward the metal plate and the first ceramic plate.

12. The method of manufacturing the bonded substrate according to claim 10, wherein, in the cutting of the stack, the stack is cut by at least one of irradiation with a water jet laser or dicing with a dicer.

13. The method of manufacturing the bonded substrate according to claim 10, wherein, in the disposing of the first bonding member, the first bonding member is an active metal brazing material.

14. The method of manufacturing the bonded substrate according to claim 10, wherein, in the firing of the first ceramic plate, the first bonding member, and the metal plate, a firing temperature is 800° C. or more and 1,100° C. or less.

15. The method of manufacturing the bonded substrate according to claim 10, wherein, in the polishing or the grinding of the second surface of the first ceramic plate, the second surface of the first ceramic plate and the first metal body are polished or ground such that the second surface of the first ceramic plate and an exposed surface of the first metal body are coplanar with each other.

16. The method of manufacturing the bonded substrate according to claim 15, further comprising:
after the polishing or the grinding of the second surface of the first ceramic plate and before cutting the stack, disposing a first electrically-conductive member on the second surface of the first ceramic plate and the exposed surface of the first metal body, and applying plating to the first electrically-conductive member.

17. The method of manufacturing the bonded substrate according to claim 11, further comprising:
after the polishing or the grinding of the second surface of the first ceramic plate and before the cutting of the stack, disposing a second electrically-conductive member on the second surface of the second ceramic plate.

18. The method of manufacturing the bonded substrate according to claim 10, wherein, in the disposing of the first bonding member in the recess and on the first surface of the first ceramic plate, the recess in the first surface of the first ceramic plate has a grid pattern in a plan view.

19. A method of manufacturing a light-emitting device, the method comprising:
manufacturing the bonded substrate by the method of claim 10; and
disposing a light-emitting element on the bonded substrate.
